(19) United States
(12) Patent Application Publication
(10) Pub. No.: US 2003/0098475 A1
(43) Pub. Date: May 29, 2003

(54) Photodiode of end face incident type

(76) Inventor: Takashi Ueda, Tokyo (JP)

Correspondence Address: VOLENTINE FRANCOS, PLLC, Suite 150, 12200 Sunrise Vally Drive, Reston, VA, 20191, US

(21) Appl. No.: 10/252,711

(22) Filed: Sep. 24, 2002

(30) Foreign Application Priority Data
Nov. 26, 2001 (JP) 359225/2001

(51) Int. Cl. H01L 27/148

(52) U.S. Cl. 257/233

(57) ABSTRACT

A photodiode 10 of end face incident type which comprises a laminate consisted of an intrinsic semiconductor layer 16 between semiconductor pn conjunction layers 14 and 15 of n-type and p-type InGaAsP. The intrinsic semiconductor layer is formed by InGaAsP to increase a light absorbing region in the intrinsic semiconductor layer 16 toward a direction of depth from the light receiving end plane so as to control light absorptance of the absorbing layer.

### FIELD OF THE INVENTION

This invention relates to a so-called pin photodiode comprising a laminate provided with an intrinsic semiconductor layer serving as a light absorbing layer between pn junction layers of semiconductor and, in particular, relates to a photodiode of end face incident type in which an end face across each semiconductor layer of the semiconductor functions as a light receiving plane.

### BACKGROUND OF THE INVENTION

According to a pin photodiode comprising an intrinsic semiconductor which functions as a light receiving layer between pn junction layers, a depletion layer having a relatively wide width can be obtained due to the intrinsic semiconductor arranged between the pn junction layers even when the pn junction exhibits relatively low pn junction voltage, thereby reducing electrostatic capacity. Thus, it is possible to obtain a photodiode having a relatively fast response according to the pin photodiode.

One of the pin photodiode includes an end face incident type wherein an end surface across pn junction layers and an intrinsic semiconductor layer between them serving as a light receiving surface.

With such a pin photodiode suited for high speed operation, a material in which wave length of band gap is shorter than that of light to be absorbed is selected as a semiconducting material for each p and n layer, while a material in which wave length of band gap is longer than that of light to be absorbed is selected as a semiconductor material for an intrinsic semiconductor layer between both pn layers, so as to promote a decrease in absorption of light in the pn junction layers and also an increase thereof in the intrinsic semiconductor layer between the pn junction layers, respectively.

Further, materials of each pn junction and intrinsic semiconductor layer are selected by considering their lattice matching.

There have been used InGaAsP or InP as the pn junction layers and InGaAs as an intrinsic semiconductor layer in a conventional photodiode of end face incident type under the above mentioned condition. More concretely, InGaAs of the intrinsic semiconductor layer is represented as In_{0.53}Ga_{0.47}As having band gap wave length of about 1.65 μm and light absorptance of about 10⁴/cm or more with regard to incident light of 1.3 μm and also 1.55 μm.

When relatively intensive incident light falls on an a light receiving surface, a great number of carrier pairs would be generated locally in the vicinity of the incident end face to counteract internal electric field in the region of depletion layer, if the light absorptance in the intrinsic semiconductor layer or light absorbing layer is high. Such a concentrated generation of carrier pairs in the vicinity of incident face causes a local disappearance or reduction of internal electric field in the region of depletion layer, which is disadvantageous for high speed operation.

Then, it is considered to reduce absorptance in the light absorbing layer, in order to prevent concentrated generation of carrier pairs to secure high speed operation. For this purpose, a percentage composition of InGaAs consisting of the light absorbing layer is controlled to reduce the band gap wave length.

However, when a desired band gap wave length is obtained by controlling a percentage composition of InGaAs, there results in considerable mismatch of lattice constant between each pn junction layer composed of InGaAs, respectively, and the light absorbing layer or intrinsic semiconductor layer sandwiched by the pn junction layers, so that desirable photodiode is hardly obtained.

Accordingly, it is an object of the invention to provide a pin photodiode of end face incident type without interfering with high speed operation properties if intensity of incident light is increased.

### SUMMARY OF THE INVENTION

In order to achieve the above mentioned object of the invention, there is provided a photodiode of end face incident type which comprises a laminate consisted of an intrinsic semiconductor layer between semiconductor pn conjunction layers of n-type and p-type InGaAsP and an end face across each laminated layer of the laminate as a light receiving plane, the intrinsic semiconductor layer being formed by InGaAsP to increase a light absorbing region in the intrinsic semiconductor layer toward a direction of depth from the light receiving end plane.

The intrinsic semiconductor layer comprises the same InGaAsP as the composition as the pn conjunction layers in which a percentage composition of In (x) in the III group elements and that of As (y) in the V group elements are selected appropriately to relevantly absorb incident light without causing substantial mismatch of lattice constant between the intrinsic semiconductor layer and the pn conjunction layers, so that more adequate band gap wave length can be effected by the present light absorbing layer compared with band gap wave length obtained by a similar conventional layer of InGaAs. As a result, it is possible to obtain so low light absorptance as, e.g. 2,500/cm, in the present light absorbing layer consisting of the intrinsic semiconductor layer, which has conventionally been about 10⁴ to 10⁵/cm.

Because of such a decrease in light absorptance, incident light falling on the light receiving plane of light absorbing layer reaches a deeper site from the light receiving end face compared with conventional one without local absorption thereof in the light receiving plane or in the vicinity of incidence end face and can be absorbed in such a deeper site. For that reason, the light absorbing region in the light absorbing layer is substantially deepened from the light receiving end plane toward the direction of depth. As a result, when relatively intensive incident light falls on the light receiving plane, the incident light is absorbed in a dispersed manner from the light receiving end plane of light absorbing layer toward the direction of depth without local absorption thereof in the vicinity of the incidence end face.

According to the invention, even when intensive incident light falls on the light receiving end plane, an amount of carrier pairs generated locally in the vicinity of the light receiving end plane is not sufficient to partially counteract the internal electric field in the region of depletion layer, so that high speed operation properties are not interfered but improved compared with conventional cases.

A semiconductor material consisted of the intrinsic semiconductor layer is represented as InₓGa₁₋ₓAs_{y}P_{1-y}, wherein x is a percentage composition of In in the III group elements and y is a percentage composition of As in the V group elements in InGaAsP of the intrinsic semiconductor layer.

There may be used a semiconductor material of InGaAsP represented by the above mentioned rational formula in which x is about 0.589 and y is about 0.863, or x is about 0.586 and y is about 0.887, respectively.

### BRIEF DESCRIPTION OF THE DRAWINGS

FIG. 1 is a perspective view of the pin photodiode of end face incident type of the invention, and it is a schematic view wherein incident light falls from the near side, i.e. from a viewer side of the drawings.

### DETAILED DESCRIPTION OF THE INVENTION

A preferred embodiment of the invention as illustration is now described in detail.

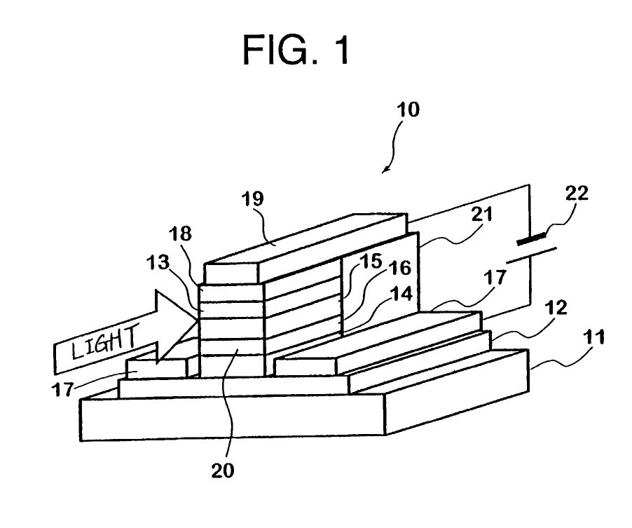

FIG. 1 is a schematic view concretely showing a photodiode of the invention.

As shown in FIG. 1, a photodiode 10 of the invention comprises a lower clad layer 12 formed on a semiconductor substrate 11 and an upper clad layer 13 formed above the lower clad layer 11 while leaving a space, guide layers 14 and 15 arranged between both clad layers 12 and 13 and an intrinsic semiconductor layer 16 arranged between both guide layers 14 and 15.

There may be used a conventional substrate such as, for example, an InP substrate added with iron (Fe) as a dopant, as the semiconductor substrate 11. As is well known conventionally, the lower clad layer 12 on the semiconductor substrate 11 is formed by a n-type InP of 0.5 μm in thickness, while carrier density thereof is, for example, 10¹⁹ atoms/cm³.

Each of semiconductor layers 14, 15 and 16 is laminated on the lower clad layer 12 and consists of a compound semiconductor represented by InₓGa₁₋ₓAs_{y}P_{1-y}, wherein x is a percent composition of indium (In) in the III group elements, i.e. indium (In) and Gallium (Ga), and y is a percentage composition of arsenic (As) in the V group elements, i.e. arsenic (As) and phosphorus (P).

As each of percent composition of n-type and p-type semiconductor layers 14 and 15 is x=0.88 and y=0.26, respectively, these layers 14 and 15 are represented by In_{0.88}Ga_{0.12}As_{0.26}P_{0.74} according to the above mentioned rational formula and have thickness of 0.8 μm, while exhibiting band gap wave length of 1.1 μm.

Of the semiconductor layers 14 and 15, silicon (Si) is added to the n-type semiconductor layer 14 as a donor in a ratio of 5×10¹⁷ atoms/cm³, while zinc (Zn) is added to the p-type semiconductor layer 15 as an acceptor in a ratio of 5×10¹⁷ atoms/cm³.

The intrinsic semiconductor layer 16 arranged between both semiconductor layers 14 and 15 consists of the same compound semiconductor represented by the formula InₓGa₁₋ₓAs_{y}P_{1-y} as the layers 14 and 15.

When wave length to be dealt with is 1.55 μm, the intrinsic semiconductor layer 16 consists of a intrinsic semiconductor represented by In_{0.586}Ga_{0.414}As_{0.887}P_{0.113}, i.e. x=0.586 and y=0.887 in the rational formula, which exhibits band gap wave length of, for example, 1.60 μm, so that incident light of the above mentioned wave length is efficiently absorbed.

Further, an intrinsic semiconductor layer 16 exhibiting band gap wave length of 1.58 μm may consist of In_{0.598}Ga_{0.402}As_{0.863}P_{0.137}.

A pair of conventionally well-known lower electrodes 17 are arranged on the lower clad layer 12 at exposed both sides of the n-type semiconductor layer 14.

The upper clad layer 13 consists of a conventionally well-known layer such as p-type InP having, e.g. 0.4 μm in thickness and e.g. 10¹⁸ atoms/cm³ in carrier density.

As is conventionally well-known, a contact layer 18 is formed on the upper clad layer 13, which consists of a p-type InGaAs layer having, e.g. 0.3 μm in thickness and e.g. 1×10¹⁹ atoms/cm³ in carrier density, while an upper electrode 19 is formed via the contact layer 18. As is also conventionally well-known, the contact layer 18 allows an ohmic contact between the upper clad layer 13 and the upper electrode 19.

A pair of clad layers 12 and 13, between which InGaAsP semiconductor layers 14, 15 and 16 are sandwiched, exhibit lower reflective index than InGaAsP and allow incident light in the InGaAsP layers 14, 15 and 16 to be sealed optically.

A light receiving plane 20 for incident light is defined on a front end face of a laminate comprising semiconductor layers 14 to 16 and 18, on which an anti-reflective film is formed, if necessary. A spacer 21 made of electrically insulating material such as polyimide is arranged on a rear face of the laminate to fill between the lower clad layer 12 and the upper electrode 19.

Each of semiconductor layers 12 to 16 and 18 may be formed by conventionally well-known reduced pressure MOCVD process.

The photodiode 10 is connected to direct-current inverse bias power supply 22 between the upper electrode 19 and the lower electrodes 17 and used under the inverse bias condition. When incident light of, for example, 1.55 μm in wave length falls on the light receiving plane 20, the incident light is mainly absorbed in the intrinsic semiconductor layer 16. Electrons and hole carrier pairs generated by such a light absorption are accelerated by junction electric field between the n-type semiconductor layer 14 and the p-type semiconductor layer 15, thereby allowing electrons to flow upward to the upper clad layer 13 and hole carrier pairs to flow downward to the lower clad layer 12, so that electric current is put out between both electrodes 17 and 19 of the photodiode 10 depending on intensity of the incident light.

In the present photodiode 10, the intrinsic semiconductor layer 16 between the n-type semiconductor layer 14 and the p-type semiconductor layer 15 consists of a compound semiconductor represented by InₓGa₁₋ₓAs_{y}P_{1-y}, which is the same composition InGaAsP of the junction layers 14 and 15.

Accordingly, compared with a conventional intrinsic semiconductor layer of InGaAs, it is possible to set larger and more pertinent band gap wave length in the intrinsic semiconductor layer 16 between the conjunction layers 14 and 15 without causing considerable mismatch of each lattice constant between them by appropriately selecting x as the percent composition of indium (In) and y as that of arsenic (As).

For example, a band gap wave length of a conventional InGaAs semiconductor layer is 1.65 μm with regard to incident light of 1.55 μm. On the other hand, according to the invention, it is possible to form an intrinsic semiconductor layer 16 which exhibits 1.60 μm in band gap wave length by use of a compound semiconductor of In_{0.586}Ga_{0.414}As_{0.887}P_{0.113}. It is also possible to form an intrinsic semiconductor layer 16 which exhibits 1.58 μm in band gap wave length by use of In_{0.598}Ga_{0.402}As_{0.863}P_{0.137} instead of the above mentioned compound semiconductor.

For example, a lower absorbance coefficient of about 2,500/cm to incident light of 1.55 μm can be attained by these intrinsic semiconductor layers 16, which is lower than conventional levels.

Because of such a reduced absorbance coefficient, incident light falling on the light receiving end plane 20 of the intrinsic semiconductor layer 16 is not locally absorbed in a shallow region of, for example, several μm in depth from the end face and allows to invade in a deeper region, so that a substantial region of light absorption in the intrinsic semiconductor layer 16 is deepened from the light receiving plane 20.

Due to an increase in depth of the light absorbing region, the incident light falling from the light receiving plane 20 to the intrinsic semiconductor layer, i.e. light absorbing layer or is dispersed and absorbed therein toward the direction of depth from the light receiving plane 20.

As a result, according to the photodiode 10 of the invention, even when intensive incident light falls on the light receiving plane 20 as an end face, an amount of carrier pairs formed locally in the vicinity of the plane 20 is not sufficient to partially counteract the internal electric field in the depletion layer region of the intrinsic semiconductor layer 16. For that reason, compared with conventional cases, it is possible to convert incident light of higher intensity to electric signals with linearly prominent conversion properties and to improve its high speed operation, which secures photoelectric conversion of photo signals of higher frequency.

As has been described above, band gap wave length of the intrinsic semiconductor layer is set at 1.5 or 1.6 μm according to the preferred embodiment of the photodiode dealing with incident light of 1.55 μm. However, band gap wave length of the intrinsic semiconductor layer or light absorbing layer 16 may be appropriately selected to adjust the absorbance coefficient in the intrinsic semiconductor layer 16 to about 2,500/cm depending on specification such as wave length or maximum intensity of incident light falling through the light receiving plane 20.

According to the pin photodiode of end face incident type of the invention, an intrinsic semiconductor layer between pn conjunction layers of n-type and p-type InGaAsP consists of the same InGaAsP as the conjunction layer having improved lattice matching properties, in which band gap wave length thereof can be set appropriately to increase a light absorbing region in the light absorbing layer consisted of the intrinsic semiconductor layer toward the direction of depth from the light receiving plane without interfering with the lattice matching properties, thereby enhancing high speed operation properties.

What is claimed is:

1. A photodiode of end face incident type which comprises a laminate consisted of an intrinsic semiconductor layer between semiconductor pn conjunction layers of n-type and p-type InGaAsP and an end face across each laminated layer of the laminate as a light receiving plane, the intrinsic semiconductor layer being formed by InGaAsP to increase a light absorbing region in the intrinsic semiconductor layer toward a direction of depth from the light receiving end plane.

2. The photodiode of end face incident type according to claim 1, wherein light absorptance in an intrinsic semiconductor layer is about 2,500/cm with regard to light to be dealt with.

3. The photodiode of end face incident type according to claim 1, wherein a percentage composition of In in the III group elements used in an intrinsic semiconductor layer of InGaAsP is about 0.589 and a percentage composition of As in the group V elements is about 0.863.

4. The photodiode of end face incident type according to claim 1, wherein a percentage composition of In in the III group elements used in an intrinsic semiconductor is about 0.586 and a percentage composition of As in the group V elements is about 0.887.
